(19) United States
(12) Patent Application Publication
(10) Pub. No.: US 2011/0035175 A1
(43) Pub. Date: Feb. 10, 2011

(54) METHOD FOR RATING SOLAR UNITS AND IMPLEMENTING APPARATUS

(76) Inventors: Michael Beer, Weimar (DE); Jens Kampmann, Marburg (DE); Boris Farnung, Freiburg (DE); Steffen Ramlow, Weimar (DE)

Correspondence Address: CLARK & BRODY, 1700 Diagonal Road, Suite 510, Alexandria, VA, 22314, US

(21) Appl. No.: 12/850,651

(22) Filed: Aug. 5, 2010

(30) Foreign Application Priority Data
Aug. 5, 2009 (DE) 10 2009 036 132.4

(51) Int. Cl. G06F 19/00; G01R 31/26

(52) U.S. Cl. 702/109; 324/761.01

(57) ABSTRACT

The present invention relates to apparatus rating solar units and to a method for rating solar units that comprises multiple acquisition of at least one input parameter and a corresponding multiple acquisition of at least one output parameter in acquisition intervals, at least one acquisition interval being varied for purposes of subsequently acquiring at least one output parameter as a function of the minimum of one acquired input parameter.

The invention also relates to a solar unit, to a computer program and to a computer program product with means implementing the rating method.

The present invention relates to a solar unit rating method comprising multiple acquisitions of at least one input parameter and a corresponding multiple acquisition of at least one output parameter in acquisition intervals, as defined in the preamble of claim 1.

The present invention moreover relates to apparatus implementing a solar unit rating method comprising an acquisition unit for multiple acquisitions both of at least one input parameter and a corresponding multiple acquisition of at least one output parameter, in acquisition intervals, as defined in the preamble of claim 6.

Furthermore the present invention relates to a solar unit, in particular a photovoltaic power system, a solar module and/or a solar cell generating solar energy as defined in the preamble of claim 10.

The invention also relates to a computer program comprising program coding means to carry out all steps of the solar unit rating method, as defined in claim 11.

Again the invention relates to a computer program product comprising computer coding means stored on a computer readable medium to carry out the solar unit rating method as defined in claim 12.

Rating methods and implementing apparatus for them, for solar units such as solar modules and solar facilities are already known from the general state of the art.

Illustratively the German patent document DE 100 26 162 C2 discloses a quality control method for photovoltaic cells and modules (pv modules). This known procedure provides that, given real ambient conditions at the site used for the particular pv modules, two current-voltage characteristic curves of the pv module be measured at different irradiation intensities having the same spectrum, thereby determining two actual characteristic curves and determining from them the series resistance and, from at least one of said curves, the peak power. Measurement optimization with respect to measurement intervals is absent from this procedure.

The German patent document DE 103 05 662 B4 furthermore discloses a procedure to measure the internal resistance of pv modules, ascertaining two pv module current-voltage characteristic curves, a first of said curves being determined under actual ambient conditions and a second such curve by simulation. In this case too measurement optimization is absent.

The German patent document DE 20 2004 001 246 U1 discloses apparatus measuring, rating and transmitting the solar radiation intensity. This apparatus comprises a defined radiation detector element to detect the solar irradiation, further supply voltage processing units such as a DC to DC voltage converter, a blocking diode, a memory, charging current monitor and DC to DC voltage converter, a data unit such as an instrument shunt, power regulating and regulating-and-control and arc processing units such as a transmitter, a DC voltage/hf coupling network and an antenna. In the design of this apparatus, the power regulator is a MMP (maximum power point) regulator and the radiation detector element is fitted with a preferred series array of solar cells in the optimized voltage range to process the test values in the regulating and control electronics. Again optimization of measurement intervals is lacking.

The German patent document DE 299 09 648 U1 moreover discloses a radiation sensor fitted with photovoltaic test cell sensitive to solar radiation received in a housing. Said sensor is designed in a way that the housing is formed of a case open at its top end with a bottom having a cable feedthrough and a wall segment rising from said bottom and enclosing a cavity and, at its upper end, having a rest surface for the test cell and/or a transparent cover for said cell. Again this disclosure lacks measurement interval optimization.

The German patent document DE 10 2006 055 642 Al discloses a procedure and apparatus to secure test values which are characteristic of the spectrum of the solar irradiation density at the site of the pv generator. A selected solar cell of the pv generator acts as the testing cell to pick up said test values. The power required to determine the said test values is provided by a processing unit linked to the pv generator. In this design too measurement interval optimization is lacking.

As a rule, when measuring the output, no power may be fed into the circuit. Accordingly the duration and selection of individual measurement intervals affects both the output of the facility and the quality of the test results. While the above state of the art does disclose local measurement procedures for pv modules performing corresponding tests, optimized measurements at selected time intervals are not disclosed.

The objective of the present invention is to circumvent the above cited and further drawbacks of the state of the art and to create a method and apparatus to optimize local acquisition of input parameters such as solar unit irradiation, the measurement intervals in particular being set for efficiency.

The main features of the invention are defined in claim 1, in claim 6, in claim 10 and in claims 11 and 12. Embodiment modes of the invention are the objects of claims 2 through 5 and 7 through 9.

The design of the present invention requires—of a rating method for solar units including the multiple acquisition of at least one input parameter and a corresponding multiple acquisition of at least one output parameter in acquisition intervals—that at least one acquisition interval be varied for a subsequent acquisition of at least one output parameter as a function of said minimum of one acquired input parameter. The concept of solar units covers solar or photovoltaic units such as solar modules, solar elements, solar cells or the like. The solar units generate electrical power from incident solar radiation. Appropriate rating methods are used to ascertain the solar unit's efficacy, that is to determine at least approximately its output. Input and output parameters under real conditions are compared to theoretical or reference parameters and a rating is then carried out. Basically the accuracy of such ratings will be raised the more frequent the local measurements are performed. However, because the solar unit must be removed from the electric grid for such measurements, that is it no longer delivers an output, the measurement should be optimized.

Accordingly, in this invention, the measurement or acquisition interval will be varied. This variation relates to input parameters, that is, another measurement is undertaken only when more effective or better measurement is feasible. The input parameters, or more generally ambient conditions, should correspond as accurately as possible to theoretical standard test conditions. For that reason, and also to circumvent expensive simulation or costly special equipment, and minimize the lost output from the solar unit caused by each measurement, further measurement/acquisition shall be undertaken only when the factual ambient conditions are within defined boundaries. To that end, said ambient conditions are acquired and/or recorded, such recording optionally being permanent. Following acquisition/recording, the ambient conditions then are compared to the standard test conditions. If the ambient conditions are within the tolerances of the standard test conditions, an acquisition/measurement then shall be started or carried out. Once measurement has been completed, the boundaries, boundary values or tolerance limits shall be refined, that is, the tolerances applied to the ambient conditions will be narrowed to carry out the acquisition/measurement. In other words, a new measurement shall be carried out only when the ambient conditions have improved. The ambient conditions or the input parameters of the rating method illustratively are the solar irradiation intensity, the module temperature and/or the external temperature as well as the time. The acquired output parameters for instance are the solar yield, illustratively in relation to the solar irradiation intensity, an optimal operational point (maximum power point—MPP) or a voltage yield, also a power ratio or performance ratio, in particular devoid of inverter effects. The parameters may be detected at least in part by measuring the characteristic curves. In particular characteristic curve measurement may be automated when started as soon as at least one parameter, especially several parameters, foremost relevant parameters are situated within a tolerance range near the standard test conditions. To reduce the number of characteristic curve measurements per unit time and to avert collecting redundant information, acquisition is carried out by predetermined algorithms that refine the boundary values and hence the range of tolerances following each measurement. By reducing the number of characteristic curve measurements entailing removing the solar unit from the electric grid with entailed output losses, said solar unit then can be run more efficiently.

In one embodiment mode of the present invention, the acquisition intervals are varied in a way that renewed acquisition of the output parameter is carried out only when a subsequently acquired input parameter has come closer, relative to a previously acquired input parameter, to a predetermined reference value. The reference value may be bounded by tolerance limits The tolerance limits may be predetermined. Following each successful measurement, the tolerance limits are set closer to the reference value, resulting in a narrower tolerance range. If input-parameter measurements/acquisitions show them to be within the narrower tolerance ranges, the rating method may be carried out again at least in part.

In a further embodiment mode of the invention, the acquisition intervals are varied in a manner that a renewed acquisition of the minimum of the output parameter shall be carried out only when a sequence of acquired input parameters has not distanced itself from a predetermined reference value relative to a previously acquired input parameter. Measurement shall be undertaken only at equal or improved ambient conditions, preferably only when they have improved. The tolerance limits are set accordingly. The tolerance limits' variation may be carried out as a function of the previous measurement. When the ambient conditions are very close to the reference value, the tolerance limits may be very close to the reference value. If, within the tolerance range, the ambient conditions deviate relative far off the reference value(s), the tolerance limits may be moved closer to the reference value, but only slightly. Such a slight change however may take place in fixed steps, for instance relative to a fixed value. However the tolerance limits also may be changed percentage-wise, illustratively the tolerance range being reduced by 10% following successful acquisition.

A still further embodiment mode of the present invention controls the acquisition of an input parameter in timed manner, in particular at predetermined intervals. The input parameters may be acquired permanently. To reduce the complexity of acquisition, the input parameters illustratively may be acquired every ten minutes. The time intervals also may be implemented as a function of the acquisitions already performed or depending on the size of the tolerance range.

Still another embodiment mode of the invention stipulates that the acquisition of the output parameters includes acquiring the characteristic curves of the solar unit. The characteristic curves also may be those current and/or voltage, in particular of a short current, an open circuit, a current at the optimal operating point, a voltage at the optimal operating point, and the like. The acquired values or characteristic curves may be of the order of seconds to hours.

The technical disclosure of this invention stipulates further—with respect to an apparatus implementing a rating method for solar units and comprising a multiple acquisition unit to acquire at least one input parameter and a corresponding multiple acquisition within the tolerance range to acquire at least one output parameter in acquisition intervals—that said acquisition unit comprise at least one acquisition segment designed to vary an acquisition interval for a subsequent acquisition of the output parameters as a function of at least one acquired input parameter. The apparatus may be a solar cell or a solar sensor measuring the solar irradiation. These together with further components may be consolidated on one or several measuring boards. Several apparatus and/or measuring boards may be coupled, for instance to synchronize acquisitions Appropriate transmission units may be provided to forward data. In this manner the data illustratively may be analyzed and/or distributed using external computers/acquisition of the output parameter as a function of at least one acquired input parameter.

In one embodiment mode of the invention, a control unit varies the acquisition intervals in a way that renewed acquisition of at least the output parameters shall be carried out only when at least one subsequently acquired input parameter has approached a predetermined reference value relative to a previously acquired input parameter. The control unit may be fitted with an appropriate logic chip or the like.

In another embodiment of the invention, a comparator unit compares the input parameters with a reference value, and accordingly the acquisition intervals vary as a function of said comparison. Rating may be implemented by means of the comparator unit. For that purpose, a reference value or a range of reference values is stored in the comparator unit. This is defined by the tolerance boundaries which are correspondingly variable. If at least one acquired input parameter falls within the tolerance range, the rating method shall be carried out. Following said rating, acquisition or measurement, the tolerance range is changed by changing the tolerance boundaries, for instance the tolerance boundaries are moved closer to the reference value.

In yet another embodiment mode of the invention, a timing unit times the acquisition of at least one input parameter. To minimize acquisition complexity, the acquisition for instance of the input parameters, that is of the ambient conditions, may be timed, as a consequence of which acquisition takes place within predetermined time intervals. In this process, the time intervals may be varied by means of the duration of acquisition.

The technical disclosure of the invention also relates to a solar unit, in particular a photovoltaic power system, a solar module and/or a solar cell used to generate electric power and fitted with apparatus of the invention to rate the solar unit's power output.

Moreover the technical disclosure of the present invention includes program coding means including a computer program to implement all steps of the method of the invention when said steps are implemented on a computer.

Last but not least, the technical disclosure of the present invention provides program coding means, including a computer program product, stored on a computer-readable medium to implement the method of the invention when the program product runs on a computer.

Further features, particulars and advantages of the invention are contained in the wording of the claims and in the description of its embodiment modes.

All features and advantages, including design details, spatial configurations and method steps found in the claims, the specification and the drawing may be construed inventive per se or in arbitrary combinations.

1. A rating method for solar units, comprising multiple acquisition of at least one input parameter and corresponding multiple acquisition of at least one output parameter in acquisition intervals,
characterized in that
at least one acquisition interval for subsequently acquiring the minimum of one output parameter is varied as a function of the minimum of one acquired input parameter.

2. Method as claimed in claim 1,
characterized in that
the acquisition intervals are varied in a manner that a renewed acquisition of at least one output parameter shall be carried out only when at least one subsequently acquired input parameter has approached a predetermined reference value relative to a previously acquired input parameter..

3. Method as claimed in either of claims 1 and 2,
characterized in that
the acquisition intervals are varied in a manner that a renewed acquisition of at least one of the output parameters shall be carried out only when a sequence of acquired input parameters has not moved away from a predetermined reference value relative to a previously acquired input parameter.

4. Method as claimed in one of the above claims 1 through 3,
characterized in that
the acquisition of at least one of the input parameters is controlled in time, in particular in predeterminable intervals.

5. Method as claimed in one of the above claims 1 through 4,
characterized in that
the output parameter acquisition includes acquiring the characteristic curves of the solar unit.

6. Apparatus with which to implement a rating method for solar units, comprising an acquisition unit for multiple acquisitions of at least one input parameter and a corresponding multiple acquisition of at least one output parameter, in acquisition intervals,
characterized in that
the acquisition unit comprises at least one acquisition segment designed to vary an acquisition interval used to subsequently acquire the output parameters as a function of at least one acquired input parameter.

7. Apparatus as claimed in claim 6,
characterized in that
it is fitted with a control unit varying the acquisition intervals in a manner that renewed acquisition of at least the output parameters shall be implemented only when at least one subsequently acquired input parameter has approached a predetermined reference value compared to a previously acquired input parameter.

8. Apparatus as claimed in either of claims 6 and 7,
characterized
by comprising a comparator unit comparing the input parameters to a reference value allowing varying the acquisition intervals as a function of the comparison.

9. Apparatus as claimed in either of above claims 7 and 8,
characterized in that
it includes a timing unit to time the acquisition of at least one input parameter.

10. A solar unit, in particular a photo-voltaic power system, a solar module and/or a solar cell, to generate solar power,
characterized in that
it is fitted with apparatus rating the power output of a solar unit as claimed in one of claims 7 through 10.

11. A computer program including program coding means to implement all steps as claimed in each of claims 1 through 6 when the program is run on a computer.

12. A computer program product including program coding means stored on a computer-readable medium, used to implement the method claims in each of claims 1 through 6, when the program product runs on a computer.
